(19) United States
(12) Patent Application Publication
(10) Pub. No.: US 2022/0056617 A1
(43) Pub. Date: Feb. 24, 2022

(54) POLYCRYSTALLINE MATERIAL, BODIES COMPRISING SAME, TOOLS COMPRISING SAME AND METHOD FOR MAKING SAME

(71) Applicant: ELEMENT SIX GMBH, Burghaun (DE)

(72) Inventors: Igor Yurievich Konyashin, Burghaun (DE); Bernd Heinrich Ries, Burghaun (DE); Frank Friedrich Lachmann, Burghaun (DE)

(73) Assignee: ELEMENT SIX GMBH, Burghaun (DE)

(21) Appl. No.: 17/453,328

(22) Filed: Nov. 2, 2021

Related U.S. Application Data
(62) Division of application No. 14/403,624, filed on Nov. 25, 2014, now abandoned.
(60) Provisional application No. 61/652,474, filed on May 29, 2012.

(30) Foreign Application Priority Data
May 29, 2012 (GB) 1209482.7

(51) Int. Cl. C30B 29/52; C22C 26/00; C22C 29/08; C22C 29/06; B22F 7/08; C22C 29/16; C22C 1/05; C23C 4/129; C23C 4/134; C23C 4/067; B32B 15/01; C21D 6/00; C22C 38/02; C22C 38/22

(52) U.S. Cl. CPC C30B 29/52; B22F 2005/001; C22C 29/08; C22C 29/067; B22F 7/08; C22C 29/16; C22C 1/053; C23C 4/129; C23C 4/134; C23C 4/067; B32B 15/011; C21D 6/002; C21D 6/008; C22C 38/02; C22C 38/22; Y10T 428/12958; C22C 26/00

(57) ABSTRACT

Polycrystalline material comprising a plurality of nano-grains of a crystalline phase of an iron group element and a plurality of crystalline grains of material including carbon (C) or nitrogen (N); each nano-grain having a mean size less than 10 nanometres.

### CROSS-REFERENCES TO RELATED APPLICATIONS

This application is a divisional of U.S. patent application Ser. No. 14/403,624, filed on Nov. 25, 2015 which is a U.S. national phase of International Application No. PCT/EP2013/060790 filed on May 24, 2013, and published in English on Dec. 5, 2013 as International Publication No. WO 2013/178554, which application claims priority to Great Britain Patent Application No. 1209482.7 filed on May 29, 2012 and U.S. Provisional Application No. 61/652,474 filed on May 29, 2012, the contents of all of which are incorporated herein by reference.

### FIELD OF THE INVENTION

This disclosure relates generally to polycrystalline material, constructions comprising same, tools comprising same and a method for making same. In particular but not exclusively, the polycrystalline material may be for use as a hard facing material to protect bodies and tools against degradation in use.

### BACKGROUND OF THE INVENTION

U.S. Pat. No. 7,662,207 discloses a bulk material composed of an aggregate of nano-size grains and having high strength or hardness. Crystal grains of magnetic elements such as iron, cobalt and nickel are reduced down to nano-size levels so as to provide a novel material showing improved soft magnetism. A nano-crystal austenite steel bulk material containing a solid-solution type nitrogen is disclosed. This disclosure also discussed that, as the Hall-Petch relationship teaches, metal material strength increases with decreasing crystal grain diameter D, and such strength dependency on grain diameter holds even at or near D=50 to 100 nanometres. Thus, reducing crystal grain diameters down to the ultra-fine, nano-size levels now becomes one of the most important means ever for the reinforcement of metal materials. Some technical journals suggest that reducing D down to ultra-fine sizes of as fine as a few nanometres may cause super-plasticity to occur. However, the crystal grain diameter D of most metal materials produced by melting are usually on the order of a few microns to a few tens of microns, and D can hardly be reduced down to the nano-order even by post-treatments. Even with controlled rolling, the lowest possible limit to grain diameters is of the order of at most 4 to 5 microns. According to the above mentioned disclosure, it is impossible to obtain materials whose grain diameters are reduced down to the nano-size level with ordinary processes.

International patent application publication number WO/2012/004292 discloses a body comprising a steel substrate and a hard face structure fused to the steel substrate. The hard face structure includes a plurality of micro-structures, a plurality of nano-structures having a mean size of less than about 200 nanometres, and a binder material. The nano-structures comprise more than about 20 weight percent W, a metal M and C; M being selected from Fe, Co and Ni or an alloy thereof. The binder material comprises more than about 3 weight percent W, more than about 2 weight percent Cr, more than about 0.5 weight percent Si, the metal M and C.

International patent application publication number WO2005092542 discloses a nano-crystalline high carbon iron alloy powder having high hardness, which comprises aggregates of high carbon iron nano-crystal grains, in which a material reinforcing the ferrite phase in the above nano-crystals is dispersed and precipitated.

There is a need to provide material having high wear resistance, particularly but not exclusively as a protective coating for tools or parts that may be subject to wear in use. There is also a need to provide such material having high fracture toughness.

### SUMMARY OF THE INVENTION

Viewed from a first aspect there is provided polycrystalline material comprising a plurality of nano-grains of a crystalline phase of an iron group element and a plurality of crystalline grains of material including carbon (C) or nitrogen (N); each nano-grain having a mean size less than 10 nanometres or less than 9 nanometres.

Various compositions, configurations, combinations and uses are envisaged by this disclosure for polycrystalline material and for constructions and tools comprising same, and the following are non-limiting, non-exhaustive examples.

Various arrangements of the nano-grains within the polycrystalline material are envisaged. In some examples, the nano-grains may be dispersed in a binder matrix comprising a crystalline phase. The polycrystalline material may comprise a contiguous aggregation of the nano-grains embedded in a binder matrix comprising a crystalline phase, the nano-grains comprised in the aggregation having respective grain boundaries between them. Each nano-grain may share a grain boundary with a crystalline phase comprised in the polycrystalline material, and in some examples each nano-grain may share a grain boundary with a crystalline phase of an iron group element having a mean size of at most about 50 nanometres. Each nano-grain may share a grain boundary with a crystalline phase binder material. The nano-grains may be dispersed in a binder having nano-hardness of at least about 0.9 GPa.

In some examples, the iron group metal may be iron, cobalt or nickel. The nano-grains may comprise austenite or ferrite; and or the nano-grains may include at least one element in elemental or compound form, selected from B, Si, Ti, V, Cr, Mn, Zr, Nb, Mo, Hf, Ta, W, Al, Cu, Mg, K, Ca, Zn, Ag, P, S and N. The nano-grains and or the crystalline grains containing carbon and or nitrogen may, for example, contain chromium carbide, chromium oxide, tungsten carbide, silicon carbide or silica, and the compound may be in solid solution. In some examples, the polycrystalline material may comprise at least about 1.0 weight percent Si, at least about 5 weight percent Cr and at least about 40 weight percent W, substantially the balance of the composite material consisting essentially of the iron group metal and carbon. In some examples, the nano-grains may be the crystalline grains of material including the carbon or nitrogen; the carbon and or nitrogen may be present in the nano-grains and the polycrystalline material may be substantially free of other kinds of crystalline phases containing carbon or nitrogen; the polycrystalline material may comprise carbon- and or nitrogen-containing crystalline grains other than the nano-grains; and or the nano-grains and other crystalline grains comprised in the polycrystalline material may contain carbon and or nitrogen.

The polycrystalline material may comprise boron (B).

The polycrystalline material may comprise crystalline grains of various materials and phases. In some examples, the polycrystalline material may comprise (crystalline) grains of carbide material, such as tungsten carbide (WC), titanium carbide, tantalum carbide, molybdenum carbide, niobium carbide, hafnium carbide or vanadium carbide. In some examples, the polycrystalline material may comprise (crystalline) grains of nitride material such as cubic boron nitride or silicon nitride; and or diamond grains; and or crystalline grains of carbo-nitride or boro-nitride material.

In some examples, the polycrystalline material may comprise crystalline grains of compound material of the form MxWyCz, where M is the iron group metal, x is a value in the range from 1 to 7, y is a value in the range from 1 to 10 and z is a value in the range from 0 to 4, the crystalline grains having a crystal structure such as that of eta-phase, theta-phase or kappa-phase carbide material.

The polycrystalline material may include a plurality of elongate or plate-like micro-structures having a mean length of at least 1 micron, a plurality of nano-structures having a mean size of less than about 200 nanometres, the micro-structures and the nano-structures being dispersed in a binder matrix; the micro-structures comprising more than 1 weight percent Cr and a phase having the formula MxWyCz, where M is the iron group metal, x is in the range from 1 to 7, y is in the range from 1 to 10 and z is in the range from 1 to 4; the nano-structures comprising the iron group metal M, C and at least about 20 weight percent W; and the binder matrix comprises at least about 5 weight percent W, at least about 0.5 weight percent Cr, at least about 0.5 weight percent Si and at least about 0.5 weight percent carbon, the rest of the matrix being the iron group metal M. Each of the micro-structures may comprise at least a region that is plate-like, the region having two major dimensions and a minor dimension that defines the thickness, the thickness of each micro-structure being at least about 0.5 micron. Each micro-structure may comprise at least about 0.5 weight percent Si. Each nano-structure my comprise at least about 0.3 weight percent Si; and at least about 0.6 weight percent Cr. The nano-structures may comprise a compound including Si, W, C and Fe. The micro-structures may be dendritic in form. The micro-structures may have a yellow or brown colour after etching in the Murakami reagent for a period in the range from about 3 seconds to about 6 seconds. The nano-structures may be the nano-grains. In some examples, the micro-structures may be the crystalline grains containing the C or N, and in some examples the nano-structures may be the nano-grains or the crystalline grains containing the C or N.

The polycrystalline material may have Vickers hardness of at least about 800 HV10; and or a Palmqvist fracture toughness of at least about 10 MPa·m^{1/2}.

The density of the polycrystalline material may be at least about 98 percent of the maximum theoretical density at ambient pressure and temperature, such as at sea level and at about 20 degrees centigrade.

Disclosed polycrystalline material may have the aspect of high hardness, high abrasive wear resistance and or high toughness. While wishing not to be bound by a particular theory, the smallness of the nano-grains being less than 10 nanometres is likely to contribute to this aspect. The nano-grains in combination with crystalline grains containing carbon or nitrogen, or the nano-grains themselves containing carbon or nitrogen may have the effect of enhancing the wear resistance of the polycrystalline material.

Viewed from a second aspect there is provided a construction comprising a structure fused to a body, the body comprising an iron group metal and the structure comprising polycrystalline material according to this disclosure. The structure may comprise a layer having mean thickness of at least about 200 microns. The body may comprise steel.

In some examples, the structure may be bonded to the body via an intermediate layer having mean thickness of at least about 1 micron and at most about 100 microns, the intermediate layer comprising dendritic or platelet-like micro-structures having the formula MₓW_{y}C_{z}, where M is the iron group metal, x is in the range from 1 to 7, y is in the range from 1 to 10 and z is in the range from 1 to 4; the micro-structures comprising more than about 1 weight percent Cr and more than about 0.5 weight percent Si.

In some examples, the structure may be a protective coating for retarding degradation of the body in use. For example, the structure may be a hard face coating for protecting the body against wear in use.

The construction may comprise super-hard material such as polycrystalline diamond (PCD) material, SiC-bonded diamond material, polycrystalline cubic boron nitride (PCBN) material and or hard-metal such as cemented carbide material.

In some examples, the construction may comprise an edge or point configured for cutting, boring into or breaking up a body or formation. The construction may be for pavement degradation or for degrading rock formations as in mining or boring into the earth.

In some examples, the construction may be for breaking up formations; the construction comprising a strike tip for impacting the formation, the strike tip comprising super-hard material and joined to a support body comprising cemented carbide, the support body attached to a base comprising steel; in which the structure is a protective layer bonded to the base.

In some examples, the construction may be for boring into a formation; the construction comprising an insert for impacting the formation, the insert comprising super-hard material attached to a tool base comprising steel; in which the structure is a protective layer fused to the tool base.

Viewed from a third aspect there is provided a tool comprising a construction according to this disclosure. The tool may be for boring into the earth and may be selected from a percussion drill bit, a rotary percussion drill bit, a rotary drill bit, a shear cutting drill bit and a roller cone drill bit. The tool may be for mining or pavement degradation, such as for road milling.

Viewed from a fourth aspect there is provided a method for making polycrystalline material according to this disclosure, the method including providing a precursor structure comprising iron (Fe) and silicon (Si), and a source of carbon (C) or nitrogen (N), in which the relative quantities of the Fe, Si and C or N are selected such that the combination of the Fe, Si and C or N has a phase liquidus temperature of at most about 1,280 degrees; the method including heating the precursor structure to a temperature of at least about 1,350 degrees centigrade at a mean rate of at least about 100 degrees centigrade per second and cooling the precursor structure to less than about 1,000 degrees centigrade at a mean rate of at least about 20 degrees per second.

Various versions, variations and combinations are envisaged for the method by this disclosure, of which the following are non-limiting and non-exhaustive examples.

The method may include combining powder comprising the Fe and powder comprising the Si with polyvinyl compound binder material including a hydroxyl group to provide slurry; and spray drying the slurry to provide a plurality of the precursor structures in the form of granules.

The method may include providing a plurality of precursor structures and screening them to provide a plurality of screened precursor structures having mean diameter of at least 20 microns and at most 5,000 microns, at most about 1,000 microns, at most about 500 microns or at most about 200 microns, and selecting at least one of the plurality of screened precursor structures.

The method may include providing and heating the precursor structure at a temperature of at least about 300 degrees centigrade and at most about 1,300 degrees centigrade for at least about 5 minutes in a vacuum or a hydrogen-containing atmosphere or other atmosphere likely to reduce the rate of oxidation, and cooling the precursor structure to below about 300 degrees centigrade prior to heating the precursor structure to a temperature of at least about 1,350 degrees centigrade at a mean rate of at least about 100 degrees centigrade per second.

In some examples, the precursor structure may comprise Fe, Si, C and chromium (Cr), in which the relative quantities of the Fe, Si, C and Cr are selected such that the combination of the Fe, Si, C and Cr has a phase liquidus temperature of at most about 1,280 degrees centigrade.

The precursor structure may include a plurality of carbide material grains, such as WC grains, which may have mean size of at least 0.1 micron and at most 10 microns. The precursor structure may include a plurality of chromium carbide particles, and or the precursor structure may comprise super-hard material.

In some examples, the precursor structure may comprise at least about 13 weight percent WC grains, at least 0.1 weight percent and at most 10 weight percent Si or Si-containing compound material, and at least 0.1 weight percent and at most 10 weight percent Cr or Cr-containing compound material, and the iron group metal.

In some examples, the precursor structure may comprise at least about 60 weight percent and at most about 80 weight percent tungsten carbide, at least about 10 weight percent and at most about 20 weight percent Fe, at least about 5 weight percent chromium carbide grains, and at least about 1.0 weight percent and at most about 5 weight percent Si grains or grains comprising a precursor compound including Si.

The precursor structure may have compressive strength of at least 2 MPa.

The precursor structure is granular in form (i.e. the precursor structure may be a granule or pellet or such like).

The method may include combining a plurality of the precursor structures to provide a unitary structure.

In some examples, the method may include introducing boron (B) into the precursor structure, in elemental or compound form.

The method may include contacting the precursor structure with a substrate, the precursor structure being at a temperature of at least about 1,350 degrees centigrade whilst in contact with the substrate, for a sufficient period of time for the precursor structure to fuse with the substrate and provide a fused structure bonded to the substrate.

The method may include heating a plurality of the precursor structures to a temperature of at least about 1,350 degrees centigrade at a mean rate of at least about 100 degrees centigrade per second, depositing the precursor structures onto a substrate whilst at the temperature, and cooling the precursor structures to less than about 1,000 degrees centigrade at a rate of at least about 20 degrees per second.

The method may include depositing a plurality of the precursor structures onto a substrate by means of a high temperature spray apparatus; for example by means of a plasma torch, laser beam torch or flame torch.

The method may include contacting a plurality of the precursor structures with a substrate such that the precursor structures form a contiguous layer.

The method may include contacting a plurality of the precursor structures with a substrate comprising iron group metal. The substrate may comprise steel, for example.

In some examples, the method may include removing at least part of the substrate body.

There is provided a granule for use in making polycrystalline material according to this disclosure, comprising iron (Fe), silicon (Si), and polyvinyl compound binder material including a hydroxyl group; the relative quantities of the Fe and Si being selected such that a combination of the Fe and Si will have a phase liquidus temperature of at most about 1,280 degrees. The granule may comprise chromium (Cr) and carbon (C), the relative quantities of the Fe, Si, Cr and C selected such that a combination of the Fe, Si, Cr and C will have a phase liquidus temperature of at most 1,280 degrees centigrade.

The granule may comprise grains of metal carbide material such as tungsten carbide or chromium carbide. The grains of metal carbide may mean size of at least about 0.1 micron and at most about 10 microns. The granule may comprise at least about 60 weight percent and at most about 80 weight percent tungsten carbide grains, at least about 10 weight percent and at most about 20 weight percent iron (Fe) grains, at least about 5 weight percent chromium carbide grains, and at least about 1 weight percent and at most about 5 weight percent silicon (Si) grains. Each granule may comprise at least one grain of super-hard material such as diamond or cBN material.

The granule may have mean diameter of at least about 20 microns and at most about 5,000 microns, at most about 1,000 microns, at most about 500 microns or at most about 200 microns.

The granule may have compressive strength of at least about 2 MPa.

Disclosed example methods may have the aspect of resulting in a very effective hard face structure intimately welded onto the body, and disclosed bodies may have improved wear retardation behaviour in use.

### BRIEF DESCRIPTION OF THE DRAWINGS

Non-limiting example arrangements will now be described with reference to the accompanying drawings, of which

FIG. 1A shows a 500× magnification scanning electron micrographs (SEM) of example polycrystalline material, FIG. 1B shows a 2,000× magnification SEM image of example polycrystalline material, FIG. 1C shows a 4,000× magnification SEM image of example polycrystalline material; and FIG. 1D shows a high resolution transmission electron microscopic (HRTEM) image of the example polycrystalline material, in which nano-grains are indicated by means of a white outline superimposed on the image;

FIG. 2A, FIG. 2B and FIG. 2C show microstructures of example polycrystalline material in the form of a layer structure fused to a steel substrate, the polycrystalline material having been etched in Murakami reagent for 4 minutes (light microscopy), of which FIG. 2A shows an image of a region proximate the surface of the layer structure, FIG. 2B shows an image of the polycrystalline material etched to a depth of 1.5 millimetres from the surface of the layer structure and FIG. 2C shows an image of the interface with the steel substrate;

FIG. 3 shows an electron diffraction image of example polycrystalline material;

FIG. 4A and FIG. 4B show transmission electron microscopic (TEM) images of example polycrystalline material;

FIG. 5 shows a schematic perspective view of an example pick tool for mining; and

FIG. 6 shows a schematic side view of an example super-hard pick tool for road milling.

### DETAILED DESCRIPTION

An example method for making example polycrystalline material in the form of a layer structure fused to a steel substrate is described below.

A powder blend having a mass of 100 kg was prepared, comprising 72.7 weight percent tungsten carbide (WC) powder having mean particle size of 1 micron, 15 weight percent iron (Fe) powder, 10 weight percent chromium carbide (Cr3C2) powder and 2.3 weight percent silicon (Si) powder. The powder blend was milled for about one hour in an attritor mill in water medium using 600 kilograms hard-metal balls and 4 kilograms organic binder based of polyvinyl-containing hydroxyl groups (product KM4034, Szchimmer and Scharz™) to provide a slurry. After milling, the slurry was spray-dried to provide granules which were screened to obtain select granules from about 100 microns to about 180 microns.

The mean compressive strength of the granules was measured selecting a plurality of the granules at random, measuring the diameter of each and compressing each between two steel plates at forces from 0.1 milli-Newtons to 900 milli-Newtons (for example, by means of an instrument of the Etewe™ GmbH company in Germany). The relationship between the degree of diametric deformation of each grain and the applied forces was measured, and the compressive strength of each grain was calculated on the basis of this measured relationship. The compressive strength of the granules was found to be in the range from about 2 mega-Pascals to about 10 mega-Pascals.

A steel substrate was provided and the granules were sprayed onto the substrate by means of a plasma torch apparatus (Plasmastar™) for atmospheric plasma spraying, operated at a current of 100 Amperes in an Ar gas flow. In the process of spraying, the granules were heated at a rate of about 300 degrees centigrade per second to a temperature about 1,400 degrees centigrade. The subsequent cooling rate was about 40 degrees centigrade per second. A contiguous layer formed from the granules was thus provided fused to the substrate, the density of the layer being close to the theoretical density and the mean thickness of the layer being about 3 millimetres. The steel substrates thus coated were heat-treated.

The Vickers HV10 hardness of the polycrystalline material layer was found to be 1,000 Vickers units and the Palmqvist fracture toughness to be 15 MPa·m^{1/2}. The Vickers hardness was measured according to the ISO standard ISO 3878 and the Palmqvist fracture toughness was measured according to the ISO standard ISO/DIS 20079. The coated steel substrates were tested by use of the ASTM G65-04 test to measure wear resistance, with uncoated steel substrates being used as controls. The mass loss due to abrasion of the control was about 820 milligrams and that of the coated steel substrate was about 80 milligrams, and the volume loss of the uncoated steel was 105.2 cubic millimetres and that of the coated steel was 6.5 cubic millimetres. This indicates that the wear resistance of the example polycrystalline material was more than 15 times higher than that of the steel substrate.

Non-limiting, example polycrystalline material provided as described above will now be described.

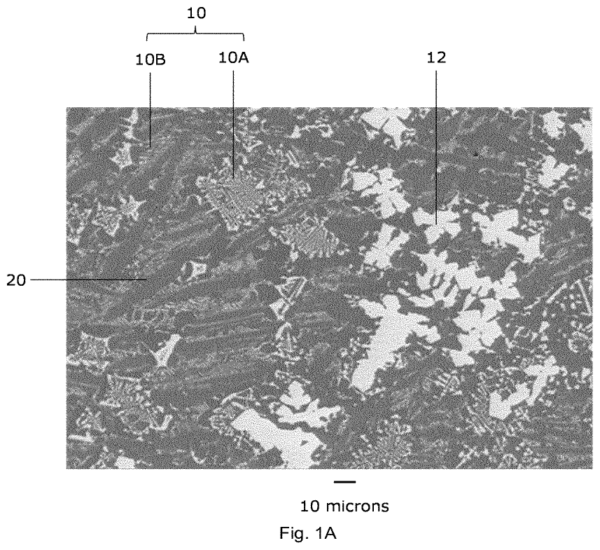

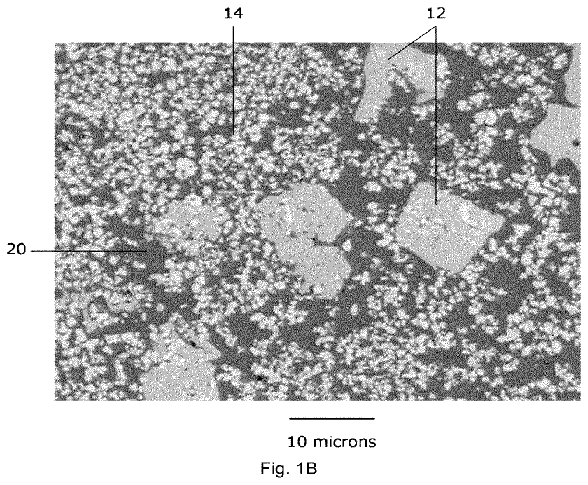

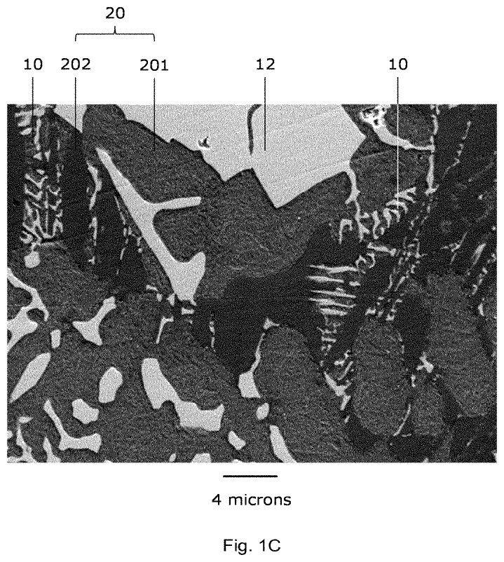

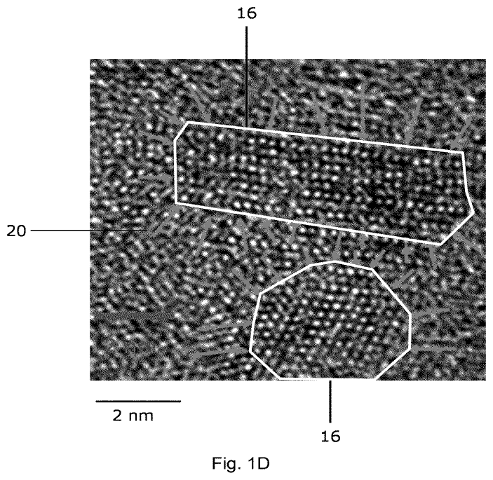

Images of the microstructure of the example polycrystalline material are shown in FIG. 1A, FIG. 1B, FIG. 1C and FIG. 1D at various magnifications. The material includes plate-like dendritic or rounded crystallite structures 10 and eta-phase carbide crystallites 12 dispersed in binder matrix 20.

The nano-hardness of the binder matrix 20 was found to be from about 1.0 GPa to about 1.3 GPa. The nano-hardness is measured by means of a TriboIndenter™ instrument (Hysitron Inc., Minneapolis, Minn., USA) with a Berkovich tip, using maximum loads of 500 micro-N and 2 mN. The loading schedule involved 10 seconds linear loading, 10 seconds hold at constant load, and 10 seconds linear unloading.

In FIG. 1A, the dendritic structure of the crystallite structures 10 is evident in some instances 10A, while the plate-like or flat aspect of the crystallite structures 10 is evident in other instances 10B that are pictured side-on.

Tungsten carbide (WC) grains 14 dispersed in the binder matrix 20 are evident in FIG. 1B.

FIG. 1C shows an electron back-scatter image of the polycrystalline material after removal of a surface layer of about 5 nanometres by means of Ar etching. The compositions of the various micro-structures and materials evident in FIG. 1C were examined by Auger electron spectroscopy (AES). The binder material 20 within which the dendritic crystallites 10, eta-phase crystallites 12 and WC crystallites 14 are embedded comprises two spatially distinct components in distinct regions 201, 202, which are evident as different shades of grey in FIG. 1C. The binder material of the first region 201 includes a plurality of the nano-grains of a crystalline phase of iron. The material of the first region 201 comprises about 24.8 weight percent W, 65.7 weight percent Fe, 3.5 weight percent Cr, 4.3 weight percent C and 1.7 weight percent Si. The binder material of the second region 202 is substantially free of the nano-grains and comprises about 29.8 weight percent W, 57.8 weight percent Fe, 4.9 weight percent Cr, 6.9 weight percent C and 0.6 weight percent Si. The dendritic structures 10 comprise about 62.4 weight percent W, 30.7 weight percent Fe, 1.8 weight percent Cr, weight percent C and 1.6 weight percent Si.

FIG. 1D shows an high resolution TEM (HRTEM) image of the binder material 20 within the first region 201, in which nano-grains 16 dispersed therein are evident. The nano-grains 16 are indicated by white boundary lines and have a mean size in the range from about 2 nanometres to about 10 nanometres. At least some of the grains 16 appear to be generally elongate and have a mean length of about 7 nanometres and mean width of about 4 nanometres. X-ray diffraction and electron diffraction indicate that the nano-grains 16 comprise crystalline phases of iron, including Fe₃W₃C, ferrite and austenite.

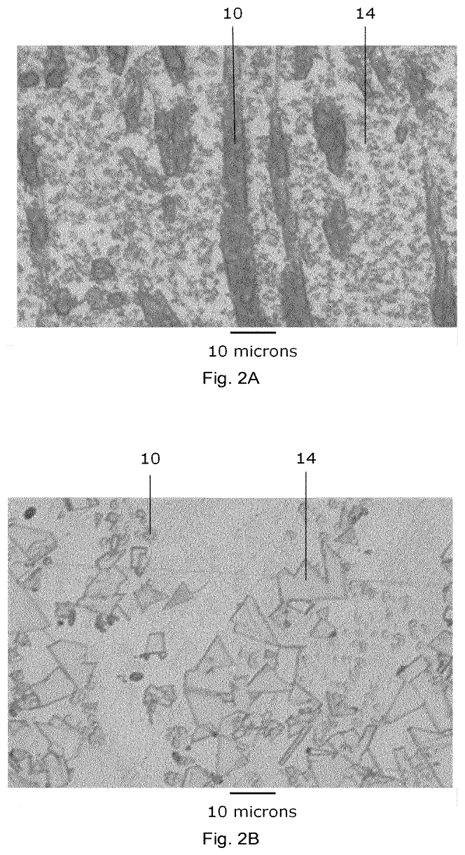

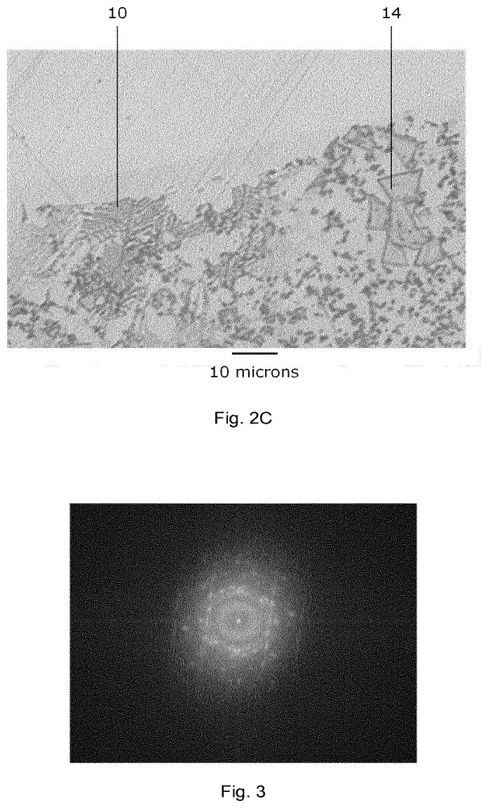

With reference to FIG. 2A, FIG. 2B and FIG. 2C, the dendritic crystallites 10 appear brown in colour after etching in Murakami reagent for about 5 seconds. The dendritic crystallites 10 comprise eta-phase carbide. Some of the dendritic crystallites 10 become black and some remain brown after further etching in the Murakami reagent for about 4 minutes WC crystallite grains 14 are also evident in example polycrystalline material.

The electron diffraction image shown in FIG. 3 indicates that the binder matrix has a nano-crystalline structure with very little amorphous phase present.

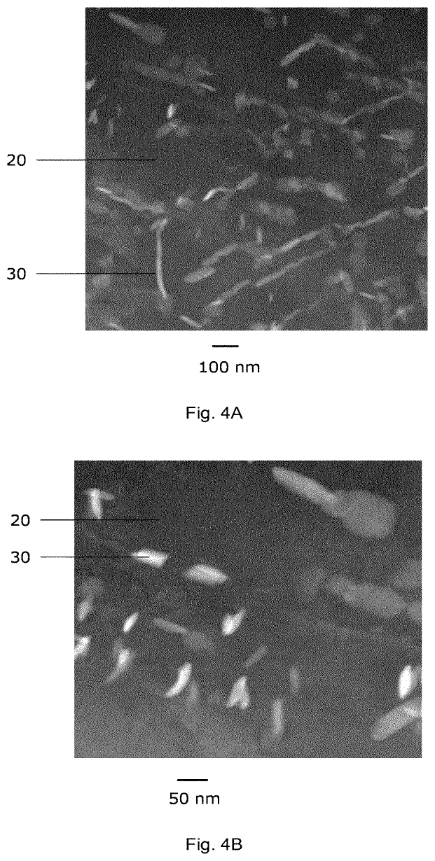

As shown in FIG. 4A and FIG. 4B, transmission electron microscopy (TEM) indicates the presence of nano-sized grains 30 of eta-phase carbide in the binder matrix 20, having the general form of nano-plates, nano-rods or nano-spheres, which are embedded in the binder matrix 20.

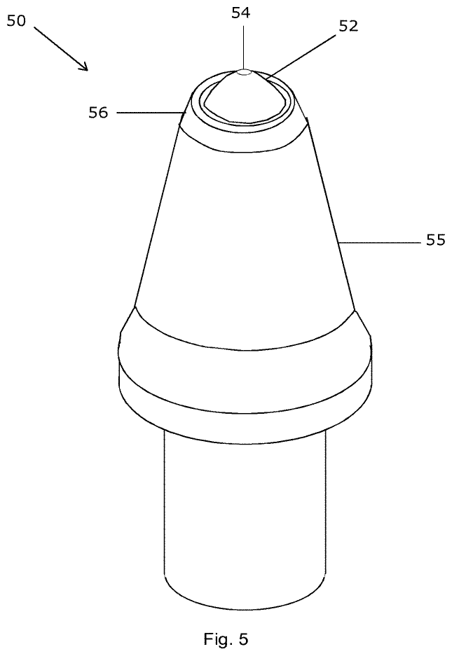

With reference to FIG. 5, an example pick tool 50 for mining comprises a steel base 55 and a hard face structure 56 fused to the steel substrate 55. The pick tool 50 comprises a cemented carbide tip 52 having a strike point 54 and joined to the steel base 55. In some examples the tip 52 may comprise diamond material such as PCD material or silicon carbide-bonded diamond material. The hard face structure 56 is arranged around the cemented carbide tip 52 to protect the steel substrate 55 from abrasive wear in use. In use breaking up a rock formation comprising coal or potash, for example, rock material may abrade the steel base 55 leading to premature failure of the pick tool 50. The hard face structure 56 comprises or consists essentially of example polycrystalline material according to this disclosure.

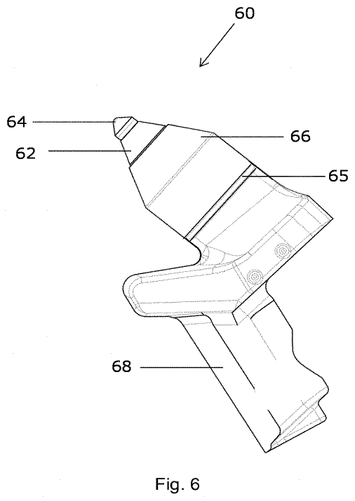

With reference to FIG. 6, an example pick tool 60 for a road pavement milling comprises a steel holder 65 provided with a bore, and a strike tip 64 joined to a cemented carbide base 62 that is shrink fit or press fit into the bore. A hard face structure 66 comprising polycrystalline material according to this disclosure is fused to the steel holder 65, arranged around the bore to protect the steel holder body 65 from wear in use. The strike tip 64 may comprise a PCD structure joined to a cemented tungsten carbide substrate. The holder 65 comprises a shank 68 for coupling to a base block (not shown) attached to a road milling drum (not shown).

As used herein in relation to grains comprised in polycrystalline material, the term “grain size” d refers to the sizes of the grains measured as follows. A surface of a body comprising the hard-metal material is prepared by polishing for investigation by means of electron backscatter diffraction (EBSD) and EBSD images of the surface are obtained by means of a high-resolution scanning electron microscope (HRSEM). Images of the surface in which the individual grains can be discerned are produced by this method and can be further analysed to provide the number distribution of the sizes d of the grains, for example. As used herein, no correction (e.g. Saltykov correction) is applied to correct the grain sizes to account for the fact that they were obtained from a two dimensional image in this way. The grain size is expressed in terms of equivalent circle diameter (ECD) according to the ISO FDIS 13067 standard. The ECD is obtained by measuring of the area A of individual grains exposed at the surface and calculating the diameter of a circle that would have the same area A, according to the equation d=square root of (4×A/π). The method is described further in section 3.3.2 of ISO FDIS 13067 entitled “Microbeam analysis—Electron Backscatter Diffraction—Measurement of average grain size” (International Standards Organisation, Geneva, Switzerland, 2011). The mean grain size D of WC grains in cemented WC material is obtained by calculating the number average of the WC grain sizes d as obtained from the EBSD images of the surface. The EBSD method of measuring the sizes of the grains has the significant advantage that each individual grain can be discerned, in contrast to certain other methods in which it may be difficult or impossible to discern individual grains from agglomerations of grains. In other words, certain other methods may be likely to give false higher values for grain size measurements.

Certain terms and concepts as used herein are briefly explained below.

As used herein, a hard face structure is a structure such as, but not limited to, a layer joined to a substrate to protect the substrate from wear. The hard face structure exhibits a substantially greater wear resistance than does the substrate.

As used herein, a wear part is a part or component that is subjected, or intended to be subjected to wearing stress in application. There are various kinds of wearing stress to which wear parts may typically be subjected such as abrasion, erosion, corrosion and other forms of chemical wear. Wear parts may comprise any of a wide variety of materials, depending on the nature and intensity of wear that the wear part is expected to endure and constraints of cost, size and mass. For example, cemented tungsten carbide is highly resistant to abrasion but due to its high density and cost is typically used only as the primary constituent of relatively small parts, such as drill bit inserts, chisels, cutting tips and the like. Larger wear parts may be used in excavation, drill bit bodies, hoppers and carriers of abrasive materials and are typically made of hard steels which are much more economical than cemented carbides in certain applications.

Pick tools may be used for breaking, degrading or boring into bodies, such as rock, asphalt, coal or concrete, for example, and may be used in applications such as mining, construction and road reconditioning. In some applications, for example road reconditioning, a plurality of pick tools may be mounted on a rotatable drum and driven against the body to be degraded as the drum is rotated against the body. Pick tools may comprise a working tip of a super-hard material, for example polycrystalline diamond (PCD), which comprises a mass of substantially inter-grown diamond grains forming a skeletal mass defining interstices between the diamond grains.

Synthetic and natural diamond, polycrystalline diamond (PCD), cubic boron nitride (cBN), polycrystalline cBN (PCBN) and silicon carbide bonded diamond (ScD) material are examples of super-hard materials. As used herein, synthetic diamond, which is also called man-made diamond, is diamond material that has been manufactured. As used herein, polycrystalline diamond (PCD) material comprises a mass (an aggregation of a plurality) of diamond grains, a substantial portion of which are directly inter-bonded with each other and in which the content of diamond is at least about 80 volume percent of the material. Interstices between the diamond grains may be at least partly filled with a binder material comprising a catalyst material for synthetic diamond, or they may be substantially empty. As used herein, a catalyst material for synthetic diamond is capable of promoting the growth of synthetic diamond grains and or the direct inter-growth of synthetic or natural diamond grains at a temperature and pressure at which synthetic or natural diamond is thermodynamically stable. Examples of catalyst materials for diamond are Fe, Ni, Co and Mn, and certain alloys including these. Bodies comprising PCD material may comprise at least a region from which catalyst material has been removed from the interstices, leaving interstitial voids between the diamond grains. As used herein, PCBN material comprises grains of cubic boron nitride (cBN) dispersed within a matrix comprising metal or ceramic material.

Other examples of superhard materials include certain composite materials comprising diamond or cBN grains held together by a matrix comprising ceramic material, such as silicon carbide (SiC), or cemented carbide material, such as Co-bonded WC material (for example, as described in U.S. Pat. No. 5,453,105 or 6,919,040). For example, certain SiC-bonded diamond materials may comprise at least about 30 volume percent diamond grains dispersed in a SiC matrix (which may contain a minor amount of Si in a form other than SiC). Examples of SiC-bonded diamond materials are described in U.S. Pat. Nos. 7,008,672; 6,709,747; 6,179,886; 6,447,852; and International Application publication number WO2009/013713).

A grain boundary is the interface between two grains, or crystallites, in a polycrystalline material. Grain boundaries are defects in the crystal structure, and tend to decrease the electrical and thermal conductivity of the material.

Several phases comprising tungsten (W), cobalt (Co) and carbon (C) are known and are typically designated by Greek letters. An eta-phase composition is understood herein to mean a carbide compound having the general formula Mx M′y C2, where M is at least one element selected from the group consisting of W, Mo, Ti, Cr, V, Ta, Hf, Zr, and Nb; M′ is at least one element selected from the group consisting of Fe, Co, Ni, and C is carbon. Where M is tungsten (W) and M′ is cobalt (Co), as is the most typical combination, then eta-phase is understood herein to mean C03W3C (eta-1) or Co6WeC (eta-2), as well as fractional sub- and super-stochiometric variations thereof. There are also some other phases in the W—Co—C system, such as theta-phases C03W6C2, Co4W4C and Co2W4C, as well as kappa-phases Co3WgC4 and CoW3C (these phases are sometimes grouped in the literature within a broader designation of eta-phase).

As used herein, the phase “consists essentially of” means “consist of, apart from practically unavoidable impurities”.

As used herein, the term “about” in relation to a value is understood to indicate a range of values explicitly including the stated value, the limits of the range being understood to be informed by the number of significant figures evident in the value as stated.

What is claimed is:

1. A method for making polycrystalline material having a plurality of nano-grains of a crystalline phase of an iron group element and a plurality of crystalline grains of material including carbon (C) or nitrogen (N), wherein each nano-grain has a mean size less than 10 nanometres and a density of the polycrystalline material is at least 98 percent of the maximum theoretical value, the method comprising:
providing a precursor structure comprising iron (Fe) and silicon (Si), and a source of carbon (C) or nitrogen (N), in which relative quantities of the Fe, Si and C or N are selected such that the combination of the Fe, Si and C or N has a phase liquidus temperature of at most 1,280 degrees centigrade;
heating the precursor structure to a temperature of at least 1,350 degrees centigrade at a mean rate of at least 100 degrees centigrade per second; and
cooling the precursor structure to less than 1,000 degrees centigrade at a mean rate of at least 20 degrees per second.

2. The method of claim 1, the method further comprising:
combining powder comprising the Fe and powder comprising the Si with polyvinyl compound binder material including a hydroxyl group to provide slurry; and
spray drying the slurry to provide a plurality of the precursor structures in a form of granules.

3. The method of claim 1, the method further comprising:
providing a plurality of precursor structures;
screening the plurality of precursor structures to provide a plurality of screened precursor structures having mean diameter of at least 20 microns and at most 5,000 microns; and
selecting at least one precursor structure from the plurality of screened precursor structures.

4. The method of claim 1, the method further comprising:
heating the precursor structure at a temperature of at least about 300 degrees centigrade and at most about 1,300 degrees centigrade for at least about 5 minutes in a vacuum or a hydrogen-containing atmosphere or other atmosphere likely to reduce a rate of oxidation; and
cooling the precursor structure to below about 300 degrees centigrade prior to including heating the precursor structure to a temperature of at least about 1,350 degrees centigrade at a mean rate of at least about 100 degrees centigrade per second.

5. The method of claim 1, in which the precursor structure comprises Fe, Si, C and chromium (Cr), in which relative quantities of the Fe, Si, C and Cr are selected such that the combination of the Fe, Si, C and Cr has a phase liquidus temperature of at most about 1,280 degrees centigrade.

6. The method of claim 1, in which the precursor structure includes a plurality of carbide material grains, such as WC grains.

7. The method of claim 1, in which the precursor structure includes a plurality of carbide material grains having mean size of at least 0.1 micron and at most 10 microns.

8. The method of claim 1, in which the precursor structure includes a plurality of chromium carbide particles.

9. The method of claim 1, in which the precursor structure contains super-hard material.

10. The method of claim 1, in which the precursor structure comprises at least 13 weight percent WC grains, 0.1-10 weight percent Si, and 0.1-10 weight percent Cr, and the iron group element.

11. The method of claim 1, in which the precursor structure comprises at least about 60 weight percent and at most about 80 weight percent tungsten carbide, at least about 10 weight percent and at most about 20 weight percent Fe, at least about 5 weight per cent chromium carbide grains, and at least about 1.0 weight percent and at most about 5 weight percent Si grains or grains comprising a precursor compound including Si.

12. The method of claim 1, in which the precursor structure has compressive strength of at least 2 MPa.

13. The method of claim 1, in which the precursor structure is granular in form.

14. The method of claim 1, the method further comprising combining a plurality of the precursor structures to provide a unitary structure.

15. The method of claim 1, the method further comprising introducing boron (B) into the precursor structure, in elemental or compound form.

16. The method of claim 1, the method further comprising contacting the precursor structure with a substrate, the precursor structure being at a temperature of at least about 1,350 degrees centigrade while in contact with the substrate, for a sufficient period of time for the precursor structure to fuse with the substrate.

17. The method of claim 1, the method further comprising:
heating a plurality of the precursor structures in granular form to a temperature of at least 1,350 degrees centigrade at a mean rate of at least 100 degrees centigrade per second;
depositing the precursor structures onto a substrate while at the temperature; and
cooling the precursor structures to less than 1,000 degrees centigrade at a rate of at least 20 degrees per second.

18. The method of claim 1, the method further comprising depositing a plurality of the precursor structures onto a substrate by means of a high temperature spray apparatus.

19. The method of claim 1, the method further comprising depositing a plurality of the precursor structures onto a substrate by means of a plasma torch, laser beam torch or flame torch.

20. The method of claim 1, the method further comprising contacting a plurality of the precursor structures with a substrate such that the precursor structures form a contiguous layer.

21. The method of claim 1, the method further comprising contacting a plurality of the precursor structures with a substrate comprising iron group metal.

22. The method of claim 1, the method further comprising contacting a plurality of the precursor structures with a substrate comprising steel.

23. The method of claim 16, the method further comprising removing at least part of a substrate body.
